(19) United States
(12) Patent Application Publication
(10) Pub. No.: US 2020/0161572 A1
(43) Pub. Date: May 21, 2020

(54) FLEXIBLE DISPLAY SUBSTRATE WITH STRESS CONTROL LAYER

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Hai ZHENG, Beijing (CN); Yao HUANG, Beijing (CN); Gaoxiang WU, Beijing (CN); Fei LIAO, Beijing (CN); Liang SONG, Beijing (CN); Yuanyuan CHAI, Beijing (CN); Liushan CHEN, Beijing (CN)

(21) Appl. No.: 16/408,950

(22) Filed: May 10, 2019

(30) Foreign Application Priority Data
Nov. 16, 2018 (CN) 201811369177.3

(51) Int. Cl. H01L 51/00; H01L 51/56; H01L 51/50; H01L 27/32

(52) U.S. Cl. CPC H01L 51/0097; H01L 51/56; H01L 27/3246; H01L 27/3276; H01L 51/5012

(57) ABSTRACT

In an embodiment, there is provided a flexible display substrate comprising: a flexible substrate; and a stress control layer and a wiring layer provided on the flexible substrate, wherein an orthographic projection of the stress control layer on the flexible substrate at least partly overlaps an orthographic projection of wirings of the wiring layer on the flexible substrate.

### CROSS REFERENCE TO RELATED APPLICATIONS

The present application claims priority to CN Application No. 201811369177.3, filed on Nov. 16, 2018, which is incorporated herein in its entirety by reference.

### FIELD

The present application relates to the field of display technologies, and in particular, to a flexible display substrate, a method of manufacturing the same, and a display device, and more particularly to a flexible display substrate having a stress control layer, a method of manufacturing the same, and a display device.

### BACKGROUND

With the development of display technology, display devices have gradually been developed toward narrow frames and even without frames. At present, the narrow frame display device is mainly typified by flexible display device such as Organic Light-Emitting Diode (OLED) display device.

The flexible display substrate is known for its thin thickness and bendability. However, in the process of bending the flexible display substrate, the bending region and the wires in the bending region may be broken due to the excessive stress applied to the bending region, causing a defect in the flexible display substrate. In addition, as the product is developed, the bending radius of the flexible display substrate is continuously reduced so that the bending region is subjected to more and more stress.

Therefore, there is a need for an improved flexible display substrate, a method of manufacturing the same, and a display device.

### SUMMARY

According to an aspect of the present disclosure, there is provided a flexible display substrate comprising: a flexible substrate; and a stress control layer and a wiring layer provided on the flexible substrate, wherein an orthographic projection of the stress control layer on the flexible substrate at least partly overlaps an orthographic projection of wirings of the wiring layer on the flexible substrate.

In some embodiments, the wiring layer is a wiring layer disposed in a frame region of the flexible substrate; and the wirings in the wiring layer are configured for binding a circuit.

In some embodiments, the wiring is a source wiring or a drain wiring.

In some embodiments, the stress control layer has an opening.

In some embodiments, the stress control layer has a mesh structure having a plurality of openings.

In some embodiments, the stress control layer is a metal layer.

In some embodiments, the flexible display substrate further comprises: a first insulating layer disposed between the stress control layer and the wiring layer.

In some embodiments, the flexible display substrate further comprises: a second insulating layer disposed between the first insulating layer and the wiring layer, the second insulating layer including a bent portion which includes an opening, wherein the orthographic projection of the opening of the bent portion on the flexible substrate overlaps with a bending region of the flexible substrate, the wiring is located partly in the opening and partly on the second insulating layer.

In some embodiments, the second insulating layer comprises a buffer layer, a gate insulating layer, and an interlayer dielectric layer; the flexible display substrate further includes: an active layer disposed between the buffer layer and the gate insulating layer, and a gate disposed between the gate insulating layer and the interlayer dielectric layer.

In some embodiments, the flexible display substrate further comprises: a second insulating layer disposed between the first insulating layer and the wiring layer, the second insulating layer having a bent portion including an opening through which a part of the first insulating layer is exposed, wherein an orthographic projection of the bent portion on the flexible substrate overlaps with the bending region of the flexible substrate, and wherein the wiring is partly located in the opening and partly on the second insulating layer.

In some embodiments, the flexible display substrate further comprises: a barrier layer and a flexible base layer disposed in sequence between the flexible substrate and the stress control layer, and a planarization layer on the wiring layer and a first electrode for a light emitting element, a pixel defining layer, a light emitting layer, and a second electrode for the light emitting element in the display region.

In some embodiments, the flexible display substrate has a display surface and a non-display surface which are oppositely disposed, the display surface having a bending region, wherein an orthographic projection of the stress control layer on the display surface at least partly located in the bending region.

According to another aspect of the present disclosure, there is provided a method of manufacturing a flexible display substrate, comprising: forming a stress control layer on the flexible substrate; and forming a wiring layer on the flexible substrate formed with the stress control layer, wherein an orthographic projection of a wiring of the wiring layer on the flexible substrate and an orthographic projection of the stress control layer on the flexible substrate at least partly overlap.

In some embodiments, the flexible display substrate has a display surface and a non-display surface which are oppositely disposed, the display surface having a bending region, and an orthographic projection of the stress control layer on the display surface is at least partly located in the bending region.

In some embodiments, the method further comprises: before forming the wiring layer on the flexible substrate formed with the stress control layer, forming a first insulating layer on the flexible substrate formed with the stress control layer, wherein forming a wiring layer on the flexible substrate formed with the stress control layer includes forming a wiring layer on the flexible substrate on which the first insulating layer is formed.

In some embodiments, n the stress control layer is a mesh structure having a plurality of openings.

In some embodiments, the method further comprises: before forming a wiring layer on the flexible substrate formed with the stress control layer, forming a second insulating layer on the flexible substrate, wherein the second insulating layer has a bent portion including an opening, and an orthographic projection of the opening of the bent portion on the flexible substrate overlaps with a bending region of the flexible substrate; wherein forming the wiring layer on the flexible substrate formed with the stress control layer includes: forming a wiring layer such that a wiring of the wiring layer is located partly in the opening and partly on the second insulating layer.

In some embodiments, the method further comprises: before forming the wiring layer on the flexible substrate formed with the stress control layer, forming a second insulating layer on the flexible substrate formed with the first insulating layer, wherein the second insulating layer has a bent portion including an opening that exposes a portion of the first insulating layer, and an orthographic projection of the bent portion on the flexible substrate overlaps with a bending region of the flexible substrate, wherein forming the wiring layer on the flexible substrate formed with the stress control layer includes: forming a wiring layer such that a wiring of the wiring layer is located partly in the opening and partly on the second insulating layer.

According to a further aspect of the present disclosure, there is provided display device comprising a flexible display substrate of any embodiments.

In some embodiments, the flexible display substrate has a display surface and a non-display surface which are oppositely disposed, the display surface has a bending region, and an orthographic projection of the stress control layer on the display surface at least partly located in the bending region.

The above brief description and the following detailed description are merely exemplary and are not intended to limit the application.

### BRIEF DESCRIPTIONS OF DRAWINGS

In order to more clearly illustrate the technical solutions in the embodiments of the present application, the drawings used in the description of the embodiments will be briefly described below. It is obvious that the drawings in the following description are only some embodiments of the present application, and other drawings can also be apparently obtained by those of ordinary skills in the art from these drawings without need of inventive efforts.

FIG. 1 is a plan view of a flexible display substrate according to an embodiment of the present application;

FIG. 2 is a schematic cross-sectional view of a flexible display substrate according to an embodiment of the present application;

FIG. 3 is a plan view of a portion of a stress control layer according to an embodiment of the present application;

FIG. 4 is a plan view of a portion of another stress control layer according to an embodiment of the present application;

FIG. 5 is a plan view of a portion of a further stress control layer according to an embodiment of the present application;

FIG. 6 is a plan view showing a partial region of another stress control layer according to an embodiment of the present application;

FIG. 7 is a schematic cross-sectional view of another flexible display substrate according to an embodiment of the present application;

FIG. 8 is a schematic diagram of a principle of bending a flexible display substrate according to an embodiment of the present application;

FIG. 9 is a diagram showing stress experienced by a flexible display substrate when being bended according to an embodiment of the present application;

FIG. 10 is a schematic diagram of a distance between a signal wiring and a neutral surface in a bending process of a flexible display substrate according to an embodiment of the present application;

FIG. 11 is a schematic diagram of a distance between a signal wiring and a neutral surface during bending process of a flexible display substrate according to another embodiment of the present application;

FIG. 12 is a flowchart of a method for manufacturing a flexible display substrate according to an embodiment of the present application;

FIG. 13 is a flowchart of a method for manufacturing a flexible display substrate according to another embodiment of the present application;

FIG. 14 is a schematic diagram of a barrier layer and a flexible base layer sequentially formed on a flexible substrate according to an embodiment of the present application;

FIG. 15 is a schematic view of a structure after a stress control layer is formed on a flexible substrate formed with a flexible base layer is formed, according to an embodiment of the present application;

FIG. 16 is a schematic view of a structure after a first insulating layer is formed on a flexible substrate on which a stress control layer is formed, according to an embodiment of the present application;

FIG. 17 is a schematic diagram of a structure in which a buffer layer, an active layer, a gate insulating layer, a gate, and an interlayer dielectric layer which are sequentially stacked on a flexible substrate on which a first insulating layer is formed, according to an embodiment of the present application; and

FIG. 18 is a schematic view of a structure after forming a wiring layer on a flexible substrate on which a second insulating layer is formed, according to an embodiment of the present application.

The drawings that are incorporated in and constitute a part of the specification illustrate the embodiments of the present application, and together with the description serve to describe and explain the principles of the present disclosure.

### DETAILED DESCRIPTION OF ILLUSTRATIVE EMBODIMENTS

For better understanding of the objects, solutions, and advantages of the present disclosure, the embodiments of the present invention will be further described in detail with reference to the accompanying drawings. It should be understood that the accompanying drawings are only some embodiments of the present application, not all of the embodiments. Those embodiments that can be apparently obtained by those of ordinary skills in the art on basis of the present disclosure without inventive efforts are all embraced within the scope of the present disclosure.

A flexible display device includes a flexible display substrate. The flexible display substrate has a display surface and a non-display surface that are oppositely disposed. The display surface has a display area and a non-display area. The non-display area includes an edge area. The edge area can be bent to the side of the non-display surface to obtain a narrow-frame or even frameless display device. When the edge region is bent to the side of the non-display surface, the region between the display region and the edge region in the non-display region will be bent. The area to be bent may often be referred to as bending area or edge bending (EB) area.

However, wirings are usually provided in the non-display area. In the process of bending the edge region to the side where the non-display surface is located, wirings in the bending region may be prone to be broken due to being subjected to a large stress, so that the bending performance of the flexible display substrate is poor.

In the flexible display substrate according to the embodiments of the present application, a stress control layer is disposed in the bending region. With the stress control layer, the flexibility of the bending region can be improved, the stress on the bending region in the bending process can be reduced, and the bending region and the wirings in the bending region can be avoided from being broken. Thereby, the occurrence of defects in the flexible display substrate can be avoided. Moreover, by providing the stress control layer, the bending radius of the flexible display substrate can be reduced, to meet the requirements on the product upgrading.

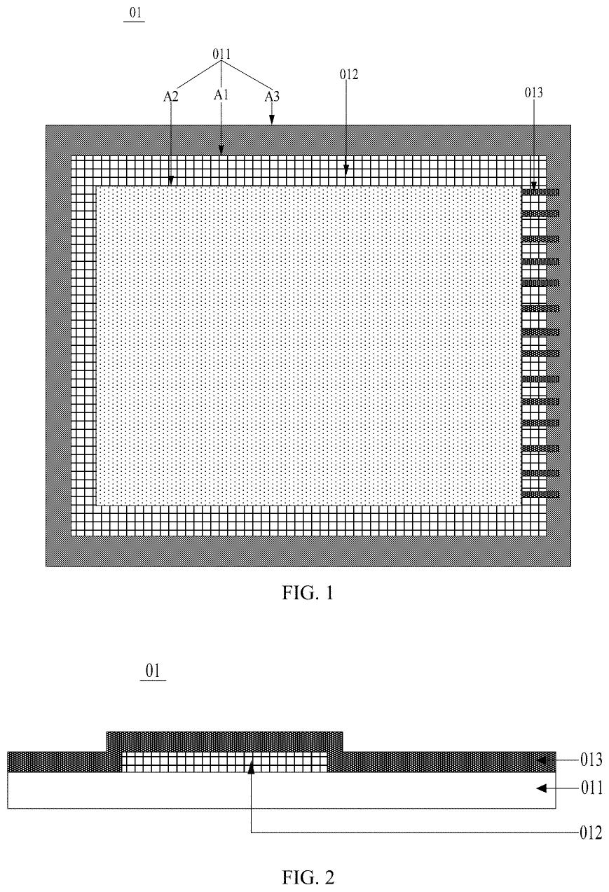

FIG. 1 is a plan view of a flexible display substrate 01 according to an embodiment of the present application. FIG. 2 is a schematic cross-sectional view of a flexible display substrate 01 according to the embodiment of the present application. Referring to FIGS. 1 and 2, the flexible display substrate 01 may include a flexible substrate 011 and a stress control layer 012 (shown in FIG. 2) and a wiring layer (not labelled in FIGS. 1 and 2) disposed on the flexible substrate 011. The flexible substrate 011 has a bent area A1. The stress control layer 012 is located at least in the bending area A1. There are wirings 013 in the wiring layer. The wirings 013 can be used to provide signals to, for example, the display area. The wiring 013 can be a lead which can be used for bonding a circuit board; but the present disclosure shall not be limited thereto. The orthographic projection of the wiring 013 on the flexible substrate 011 is at least partly located in the bending region A1. The stress control layer 012 is used to reduce the stress between the flexible substrate 011 and the signal wirings 013.

In some embodiments, the stress control layer is configured such that when the flexible display substrate is bent through the bendable region, the wiring layer is closer to a neutral surface as compared to the case where there is no such stress control layer in the flexible display substrate. Those skilled in the art will readily appreciate that a flexible display substrate (or a portion thereof) may exhibit such a surface within the flexible display substrate (or the portion thereof) when being bended that is subjected to substantially zero stress. The same is true for the case where a part of the flexible display substrate is bent.

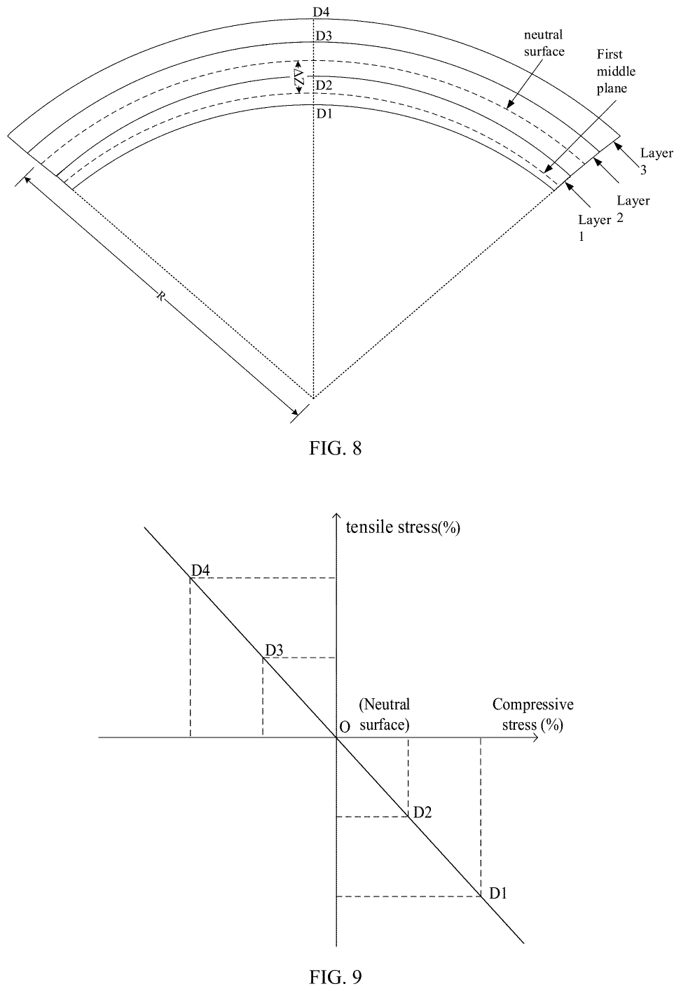

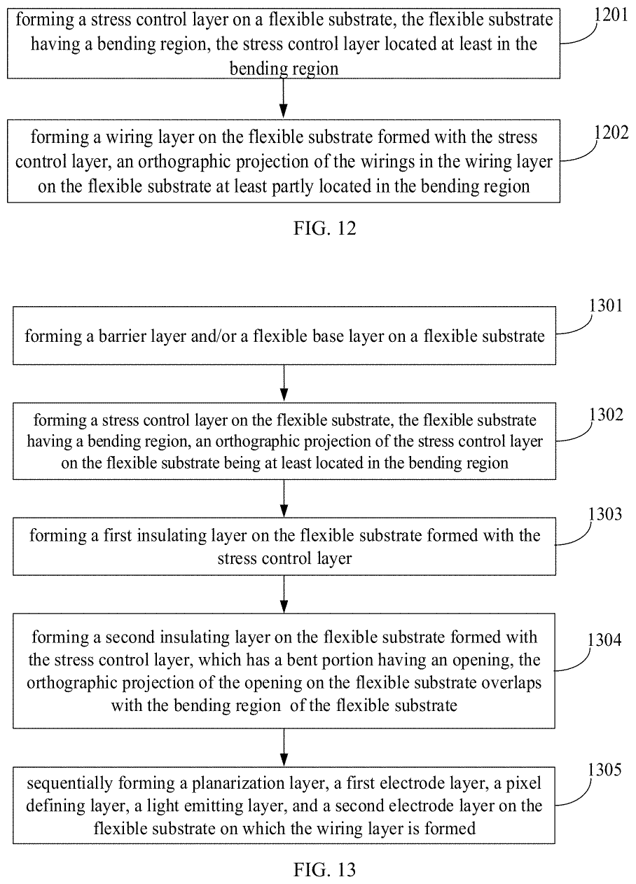

FIG. 8 is a schematic view showing the principle of bending of a flexible display substrate. FIG. 8 only schematically shows three representative film layers of the flexible display substrate, and in FIG. 8 it does not need to define what these three film layers specifically are. Referring to FIG. 8, in the bending process, the inner film layer in the flexible display substrate (referring to the film layer between a side of the neutral surface and the center of curvature of the flexible display substrate, such as the film layer 1) is subjected to compressive stress, and the outer film layer (referring to the film layer on the other side of the neutral surface, such as film layer 3) is subjected to tensile stress. Also, as shown in FIG. 8, in the bending process, a neutral surface appears in the flexible display substrate, and the neutral surface is subjected to a stress of zero. The stress experienced by each film layer can be expressed by the formula S=ΔZ/πR, where ΔZ represents the distance between the film layer and the neutral surface, and S represents the stress (which may be compressive stress or tensile stress) of the film layer, and R indicates the bend radius (the distance between the neutral surface and the center of curvature). It can be seen from FIG. 8 that the stress applied to each film layer is proportional to the distance between the film layer and the neutral surface, thus the farther the inner film is from the neutral surface, the greater the compressive stress that it is subjected to, and the further the outer layer is away from the neutral surface, the greater the tensile stress it is subjected to. It should be noted that since each film layer has a certain thickness, the points located at different thicknesses in the each film layer are subjected to different stresses. In some examples, ΔZ may represent the distance between a point of a first middle plane of each film layer (the middle plane being parallel to the surface of the film layer, such as the first middle plane of film layer 1 as shown in FIG. 12), which has the greatest bending magnitude, and the neutral surface, and S represents the stress at the point which has the greatest bending magnitude.

FIG. 9 is a diagram showing stresses at different positions of the flexible display substrate as shown in FIG. 8 when the flexible display substrate is bent. It can be seen that the neutral surface is subjected to a stress of zero. For the points D1, D2, D3, and D4, the point D1 receives the maximum compressive stress, and the point D4 receives the maximum tensile stress. It should be noted that both the neutral surface and the first middle plane are virtual surfaces, and are not actually-existing surfaces in the flexible display substrate. The neutral surface varies with the structure of the flexible display substrate.

According to the flexible display substrate of the embodiments of the present application, the flexible substrate has a stress control layer which can be located at the bending region, thus the stress on the wirings at the bending region of the flexible display substrate in the bending of the flexible display substrate can be reduced. Thereby, it is possible to avoid breakage of the wirings during the bending process and improve the bending performance of the flexible display substrate.

In some embodiments, the flexible substrate 011 may be a substrate formed of polyimide (PI).

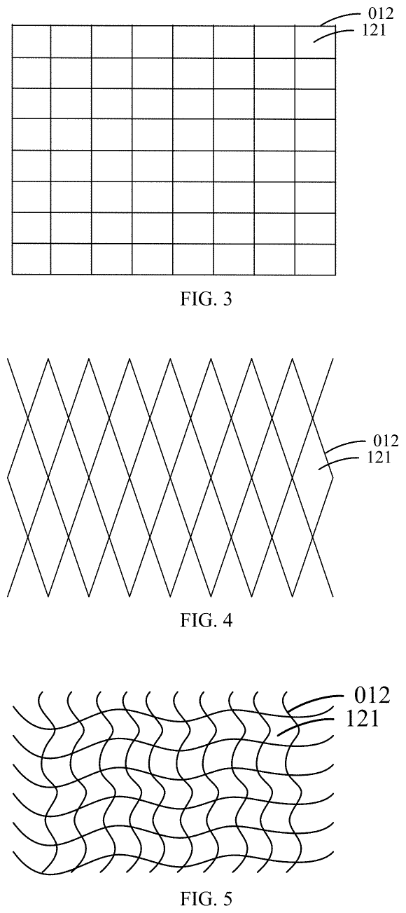

Optionally, as shown in FIGS. 1 and 2, the stress control layer 012 is located at least at the bending area A1. The stress control layer can be configured to have an opening. Optionally, the stress control layer 012 may have a mesh structure. The mesh structure may have a plurality of openings 121. The lattice of the mesh structure may be a rectangular mesh, a squad mesh, a diamond mesh, or an irregular mesh. The surface of the stress control layer 012 may be a flat surface or a non-flat surface. FIGS. 3 to 5 are plan views of partial regions of different stress control layers 012 according to embodiments of the present application. In some embodiments, the stress control layer 012 can be any mesh structure shown in any of FIGS. 3-5. In some embodiments, the surface of the stress control layer 012 can be a non-flat surface, as shown in FIG. 5. The non-flat surface can change the distributions or shapes of the signal wirings, thereby avoiding breakage of the signal wirings caused by the bending process. Here, the surface of the stress control layer 012 described herein refers to the surface of the stress control layer 012 which is away from the flexible substrate 011.

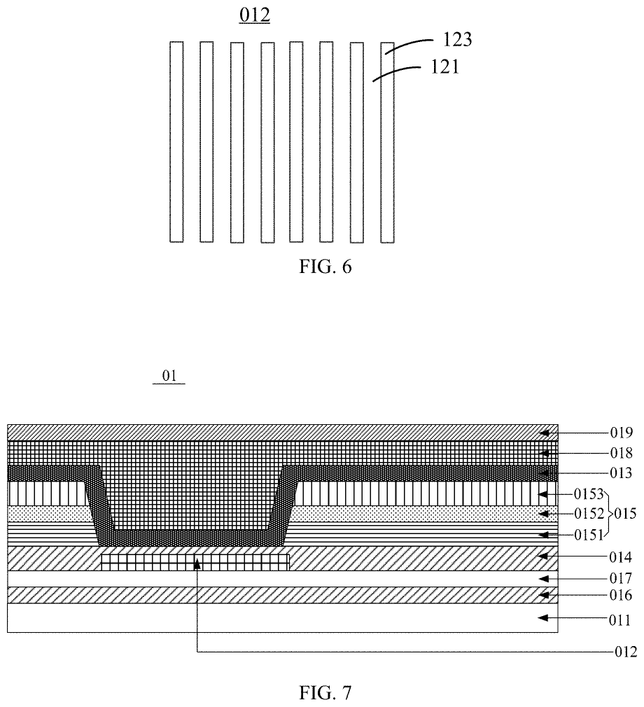

FIG. 6 is a plan view of a portion of another stress control layer 012 according to an embodiment of the present application. Referring to FIG. 6, the stress control layer 012 comprises a plurality of stress control strips 123 extending in the same direction. The length directions of the plurality of stress control strips may be parallel to each other. According to this embodiment, the stress control layer 012 can make the surface(s) of the film layer(s) between the stress control layer 012 and the wirings have a depressed portion thereon, and the wirings in the bending region can be embedded in the film layers thereunder, thus the wirings can be avoided from breakage in the bending process.

In the embodiment of the present application, the forming material of the stress control layer 012 may be metal or non-metal. If the material forming the stress control layer 012 is metal and the structure of the stress control layer 012 is a mesh structure, the stress control layer 012 may also be referred to as a metal mesh layer or a metal mesh. If the forming material of the stress control layer 012 is metal and the stress control layer 012 have a plurality of stress control strips extending in a same direction, each of the stress control strips may be a metal strip. The metal used may be selected from the group consisting of molybdenum (Mo), copper (Cu), aluminum (Al), titanium (Ti), and any alloy thereof. The stress control layer 012 can also be formed of a non-metallic material that is soft and flexible.

Refer to FIG. 7, FIG. 7 is a cross-sectional view of a flexible display substrate 01 according to another embodiment of the present application. FIG. 7 illustrates a case where the stress control layer 012 is a metal mesh layer. Referring to FIG. 7, on the basis of FIG. 2, the flexible display substrate 01 may further include: a first insulating layer 014 disposed between the stress control layer 012 and the wiring layer (which includes the wirings 013). The first insulating layer 014 may be composed of at least one insulating film layer. In some implementations, the stress control layer can be disposed on a flexible substrate or a barrier layer on a flexible substrate. A portion of the first insulating layer 014 may also be formed on the barrier layer. In some implementations, the first insulating layer 014 can be formed from the same material as the barrier layer. The first insulating layer 014 may include an inorganic material such as silicon oxide (SiOx), silicon nitride (SiNx), alumina (Al₂O₃), or silicon oxynitride (SiOxNy); or, the first insulating layer 014 may include an organic insulating material.

Since the wiring 013 is electrically conductive, the first insulating layer 014 is provided such that the stress control layer 012 (when it is electrically conductive) and the wiring 013 are insulated from each other, thereby avoiding the stress control layer 012 from affecting the signal on the wirings 013. The wirings 013 can generally be fabricated using a material selected from the group consisting of Mo, Cu, Al, Ti, and any alloy thereof.

In some embodiments, the flexible display substrate 01 may further include: a second insulating layer 015, as shown in FIG. 7. The second insulating layer 015 has a bent portion (not labelled in FIG. 7), and the bent portion has an opening. The orthographic projection of the opening of the bent portion on the flexible substrate 011 overlaps with the bending region A1 (not labelled in FIG. 7) of the flexible substrate 011. In some implementations, the wirings 013 can be configured to be partly located in the bend portion and partly on the second insulating layer 015. Optionally, the orthographic projection of the bent portion on the flexible substrate 011 covers the bending region A1 of the flexible substrate 011. Optionally, the orthographic projection of the bent portion on the flexible substrate 011 coincides with the bending region A1 of the flexible substrate 011. With the bent portion provided on the second insulating layer 015 corresponding to the bending region Al of the flexible substrate 011, the thickness of the bending region of the flexible display substrate 01 can be made small, thereby facilitating the bending of the flexible display substrate 01. The bending region of the flexible display substrate 01 is the region of the flexible display substrate 01 corresponding to the bending region A1 of the flexible substrate 011. This bending region will be bent when bending the flexible display substrate.

In the embodiment shown in FIG. 7, the second insulating layer 015 is disposed between the first insulating layer 014 and the wiring layer. However, it is to be understood that the present disclosure shall not be limited thereto. For example, in other embodiments of the present disclosure, the flexible display substrate may not include the first insulating layer in the case where the stress control layer 012 is not electrically conductive. Thus, it will be appreciated that in other embodiments, the second insulating layer can be disposed on the flexible substrate or a barrier layer on the flexible substrate.

Optionally, wirings 013 may include source/drain wirings. Referring to FIG. 7, the second insulating layer 015 may include: a buffer layer 0151, a gate insulating (GI) layer 0152, and an inter-layer dielectric (ILD) layer 0153 disposed in sequence between the first insulating layer 014 and the wiring layer. In some embodiments, the buffer layer is disposed between the gate insulating layer and the buffer layer. The flexible display substrate 01 may further include an active layer (not shown in FIG. 7) disposed between the buffer layer 0151 and the gate insulating layer 0152, and a gate (not shown in FIG. 7) disposed between the gate insulating layer 0152 and the interlayer dielectric layer 0153. In some embodiments, the second insulating layer 015 can be considered as being formed from portions of the buffer layer 0151, the gate insulating layer 0152, and the interlayer dielectric layer 0153 extending to the non-display region of the flexible display substrate 01.

In the embodiment of the present application, each of the buffer layer 0151, the gate insulating layer 0152, and the interlayer dielectric layer 0153 may be composed of at least one film layer. The buffer layer 0151, the gate insulating layer 0152, and the interlayer dielectric layer 0153 may each be formed of inorganic material such as SiOx, SiNx, Al₂O₃, SiOxNy, or the like. Optionally, the buffer layer 0151, the gate insulating layer 0152, and the interlayer dielectric layer 0153 may each be formed of organic insulating material. The materials for forming the buffer layer 0151, the gate insulating layer 0152, and the interlayer dielectric layer 0153 may be the same or different. The active layer may include, but is not limited to, an amorphous silicon (a-si) active layer, an oxide active layer, or a low temperature polysilicon (LTTP) active layer. The oxide active layer may include, but is not limited to, an indium gallium zinc oxide (IGZO) active layer, indium tin zinc oxide (ITZO) active layer, or the like. The material for forming the gate electrode may be selected from the group consisting of Mo, Cu, Al, Ti, and any alloy thereof.

In some embodiments, referring to FIG. 7, the flexible display substrate 01 may further include: a barrier layer 016 and/or a flexible base layer 017 disposed between the flexible substrate 011 and the stress control layer 012 in sequence. The barrier layer 016 may be formed of inorganic material such as SiOx, SiNx, Al₂O₃ or SiOxNy, or the barrier layer 016 may be formed of organic insulating material. The flexible base layer 017 may be formed of PI, and thus the flexible base layer 017 may also be referred to as a PI layer.

Optionally, the flexible display substrate 01 according to the embodiment of the present application may be, but not limited to, an OLED display substrate. As shown in FIG. 7, the flexible display substrate 01 may further include: a planarization (PLN) layer 018 and a pixel defining layer (PDL) 019, an anode layer, a light-emitting layer, and a cathode. The light emitting layer may be an organic light emitting layer. The anode, the light-emitting layer and the cathode form an OLED unit. In addition, when the flexible display substrate 01 is an OLED display substrate, the flexible display substrate 01 may further include components such as a photo spacer (PS) layer and a package structure. The planarization layer 018, the pixel defining layer 019, and the photo spacer layer may each be formed of organic resin. The anode and the cathode may be formed of indium tin oxide (ITO), indium zinc oxide (IZO), or aluminum-doped zinc oxide (ZnO: Al). The light emitting layer may be formed of an organic light emitting material, an electroluminescent material, or a photoluminescent material. The package structure can be a package cover or a thin film package structure. Those skilled in the art will appreciate that the planarization layer, the pixel defining layer, the anode layer, the light-emitting layer, the cathode layer, the photo spacer layer, the package structure, and the like can be implemented using materials and methods known in the art or developed in the future; therefore, the detail descriptions thereof are omitted here.

It should be noted that, in some embodiments, the flexible display substrate 01 may have multiple wiring layers, and the wirings in different wiring layers may be different. For example, the wirings in some wiring layers are source and drain wirings, while the wirings in some other wiring layers are gate wirings. In some scenarios, source or drain wirings are also referred to as data lines, and gate wirings are also referred to as gate lines. The flexible display substrate 01 may also include circuitry for driving the display elements (e.g., OLEDs). The circuitry can include transistors that can include sources, drains, and gates. The source electrode and the drain electrode are respectively connected to the active layer. The gates of some of the transistors may be connected to the gate lines, and ones of the sources and drains of some transistors are connected to the data lines. One of the source and the drain of the driving transistor may be connected to one electrode of the OLED to drive the OLED to emit light.

It should also be noted that, as shown in FIG. 1, the flexible substrate 011 has a display area A2 and a non-display area (not labelled in FIG. 1). The non-display area includes a bending area A1 and an edge area A3, and the bending area A1 is located between the display area A2 and the edge area A3. FIGS. 2 and 7 are schematic cross-sectional views showing a non-display area of the flexible display substrate 01 shown in FIG. 1. Since the structures such as the TFT and the OLED unit are usually located in the display area A2 of the flexible display substrate 01, the structures of the TFT and the OLED unit and the like are not shown in FIGS. 2 and 7. It should be understood that the relationship between the areas of the respective regions shown in FIG. 1 does not represent its relationship in the actual product, and in the actual product, the area of the display area A2 is usually much larger than the area of the non-display area. The number and distribution locations of wirings 013 shown in FIG. 1 are merely exemplary, and an actual flexible display substrate may include more or fewer wirings than the flexible display substrate 01 described herein. In addition, the wirings may be located on the other side of the display area A2, such as on the left side, the upper side, and/or the lower side of the display area A2 shown in FIG. 2. Moreover, the actual flexible display substrate can include more or less structures than the flexible display substrate 01 described herein. For example, the flexible display substrate may include a plurality of gate layers (each gate layer including a plurality of gates), a plurality of gate insulating layers, and the like. The present disclosure shall not be limited to the embodiments disclosed herein.

Hereinafter, descriptions are given on the stress control layer 012 reducing the stress between the flexible substrate 011 and the wiring 013 in the flexible display substrate 01 according to the embodiments of the present application.

FIG. 8 is a schematic view showing the principle of bending of a flexible display substrate. FIG. 8 only schematically shows three representative film layers of the flexible display substrate, and in FIG. 8 it does not need to define what these three film layers specifically are. Referring to FIG. 8, in the bending process, the inner film layer in the flexible display substrate (referring to the film layer between a side of the neutral surface and the center of curvature of the flexible display substrate, such as the film layer 1) is subjected to compressive stress, and the outer film layer (referring to the film layer on the other side of the neutral surface, such as film layer 3) is subjected to tensile stress. Also, as shown in FIG. 8, in the bending process, a neutral surface appears in the flexible display substrate, and the neutral surface is subjected to a stress of zero. The stress experienced by each film layer can be expressed by the formula S=ΔZ/πR, where ΔZ represents the distance between the film layer and the neutral surface, and S represents the stress (which may be compressive stress or tensile stress) of the film layer, and R indicates the bend radius (the distance between the neutral surface and the center of curvature). It can be seen from FIG. 8 that the stress applied to each film layer is proportional to the distance between the film layer and the neutral surface, thus the farther the inner film is from the neutral surface, the greater the compressive stress that it is subjected to, and the further the outer layer is away from the neutral surface, the greater the tensile stress it is subjected to. It should be noted that since each film layer has a certain thickness, the points located at different thicknesses in the each film layer are subjected to different stresses. In some examples, ΔZ may represent the distance between a point of a first middle plane of each film layer (the middle plane being parallel to the surface of the film layer, such as the first middle plane of film layer 1 as shown in FIG. 12), which has the greatest bending magnitude, and the neutral surface, and S represents the stress at the point which has the greatest bending magnitude.

FIG. 9 is a diagram showing stresses at different positions of the flexible display substrate as shown in FIG. 8 when the flexible display substrate is bent. It can be seen that the neutral surface is subjected to a stress of zero. For the points D1, D2, D3, and D4, the point D1 receives the maximum compressive stress, and the point D4 receives the maximum tensile stress. It should be noted that both the neutral surface and the first middle plane are virtual surfaces, and are not actually-existing surfaces in the flexible display substrate. The neutral surface varies with the structure of the flexible display substrate.

In the flexible display substrate, in order to avoid the breakage of the wirings caused by the bending process, the wirings are usually placed in the compressive stress region (that is, the wiring layer is set as the inner film layer), so that the wirings are subjected to compressive stress during the bending process. In addition, the compressive stress experienced by the wirings is configured to be not too large.

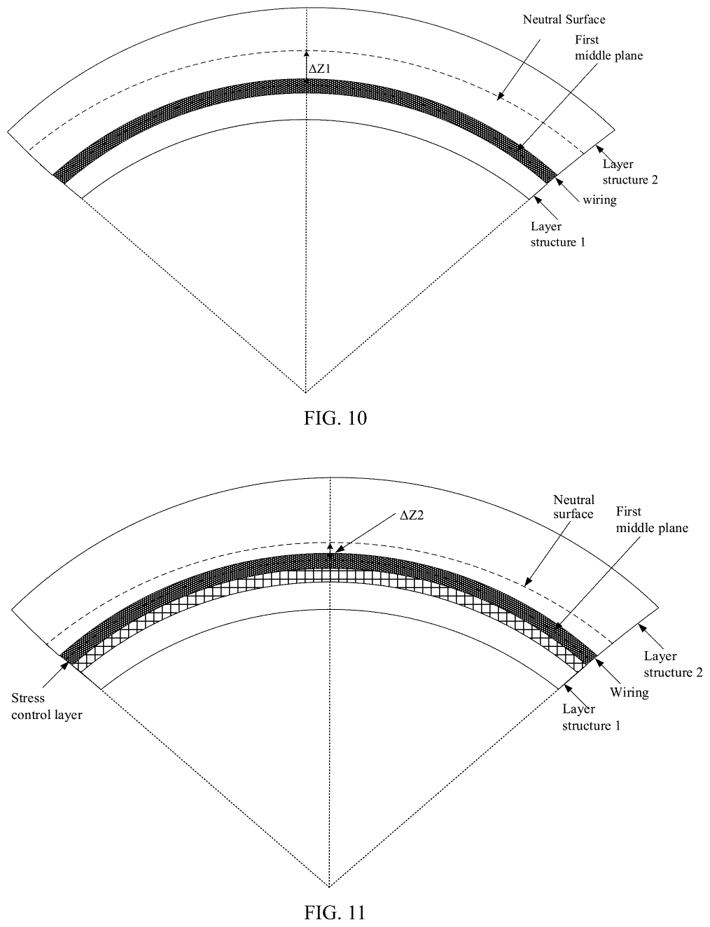

FIG. 10 is a schematic diagram of the distance between a wiring and a neutral surface in a flexible display substrate, in which no stress control layer is provided, when being bent. FIG. 11 is a schematic diagram of a distance between a wiring and a neutral surface in a flexible display substrate provided with a stress control layer according to an embodiment of the present application during a bending process. The difference between the flexible display substrates shown in FIGS. 10 and 11 is only that the stress control layer is provided in FIG. 11.

Referring to FIGS. 10 and 11, the film structure 1 represents a flexible substrate and all film layers between the wirings and the flexible substrate, and the film structure 2 represents all the layers on the side of the wiring layer which is away from the flexible substrate. The first insulating layer is not shown in FIG. 11. The distance between the wiring and the neutral surface in the flexible display substrate without the stress control layer during the bending process is ΔZ1, and the distance between the wiring and the neutral surface in the flexible display substrate with the stress control layer during the bending process is ΔZ2. As can be seen by comparing FIG. 10 and FIG. 11, the providing of the stress control layer can move the neutral surface toward the direction of the wiring, so that the distance between the neutral surface and the wiring can be reduced. From the formula S=ΔZ/πR, it can be known that the flexible display substrate provided with the stress control layer has a reduced stress on the wiring during the bending process as compared to the flexible display substrate in which the stress control layer is not provided. According to the embodiments of the present disclosure, it is possible to control and alleviate the stress of the bending region. Therefore, the wiring breakage due to the bending process can be prevented, and the bending performance of the wirings can be improved, thereby improving the bending performance of the flexible display substrate.

In addition, since in the flexible display substrate provided with the stress control layer the wirings is subjected to less stress during the bending process, the bending radius of the flexible display substrate provided with the stress control layer can be made smaller, and easier to achieve narrow-frame display.

In the flexible display substrate according to the embodiments of the present application, by providing a stress control layer in a bending region of the flexible substrate, in the bending region the stress can be concentrated on the stress control layer during the bending process of the flexible display substrate, thereby reducing the stress on the wirings. Thus, it is possible to avoid the breakage of the wirings during the bending process, and to protect the wirings. The stress control layer may be a metal mesh layer which can have good flexibility. The providing of the stress control layer can improve the flexibility of the bending region of the flexible display substrate to a certain extent, and avoid the breakage of the bending region during the bending process. In addition, since the stress on the wirings can be reduced in the case that the stress control layer is provided, the bending radius of the flexible display substrate being bent can be reduced in the bearable range of stress which the wirings can withstand, thereby facilitating achieving the narrow-frame display device.

In summary, according to the flexible display substrate according to the embodiments of the present application, the bending performance of the flexible display substrate can be improved.

According to embodiments of the present application, a method of manufacturing a flexible display substrate is also provided. The manufacturing methods of the flexible display substrate according to the embodiments of the present application will be described hereinafter in connection with the following embodiments.

FIG. 12 is a flowchart of a method for manufacturing a flexible display substrate according to an embodiment of the present application. As an example, the method can be used to manufacture the flexible display substrate 01 shown in FIG. 1, FIG. 2 or FIG. 7. Referring to FIG. 12, the method can include the following steps.

Step 1201, forming a stress control layer on a flexible substrate. The flexible substrate has a bending region. The stress control layer is located at least at the bending region.

Step 1202: forming a wiring layer on the flexible substrate formed with the stress control layer. An orthographic projection of the wirings in the wiring layer on the flexible substrate is at least partly located in the bending region.

The stress control layer is used to reduce the stress between the flexible substrate and the wiring.

According to the embodiments of the present application, the stress on the wirings in the bending region of the flexible display substrate can be reduced, the breakage of the wirings during the bending process can be avoided, and the bending performance of the flexible display substrate can be improved.

In some embodiments, the stress control layer is configured such that when the flexible display substrate is bent through the bendable region, the wiring layer is closer to the neutral surface as compared to the flexible display substrate in which the stress control layer is not present.

Optionally, the stress control layer is located at least in the bending region and the stress control layer has an opening.

Optionally, the stress control layer may have a mesh structure. Optionally, the stress control layer is a metal mesh layer.

In some embodiments, prior to step 1202, the method further includes forming a first insulating layer on the flexible substrate formed with the stress control layer. Correspondingly, step 1202 may include forming a wiring layer on the flexible substrate on which the first insulating layer is formed.

Optionally, the method may further include: before forming the wiring layer on the flexible substrate formed with the stress control layer, forming a second insulating layer on the flexible substrate. The second insulating layer has a bent portion, and the bent portion includes an opening. The opening exposes a portion of the first insulating layer. An orthographic projection of the opening of the bend portion on the flexible substrate overlaps the bending region of the flexible substrate. In some embodiments, forming the wiring layer on the flexible substrate formed with the stress control layer includes: forming a wiring layer such that the wirings is located partly in the opening and partly located on the second insulation layer.

Optionally, before forming the wiring layer on the flexible substrate on which the first insulating layer is formed, the method further comprises: forming a second insulating layer on the flexible substrate formed with the first insulating layer. The second insulating layer has a bent portion. The bent portion includes an opening. The orthographic projection of the opening on the flexible substrate overlaps the bending region of the flexible substrate. In some embodiments, forming a wiring layer on the flexible substrate on which the first insulating layer is formed includes: forming a wiring layer on the flexible substrate on which the second insulating layer is formed, and wiring(s) in the wiring layer is located partly in the bent portion and partly on the second insulating layer.

Optionally, the wirings include source and drain wirings.

In some embodiments, forming the second insulating layer on the flexible substrate on which the first insulating layer is formed includes: sequentially forming a buffer layer, a gate insulating layer, and an interlayer dielectric on the flexible substrate on which the first insulating layer is formed. In some embodiments, the method further includes: forming an active layer between the buffer layer and the gate insulating layer; and forming a gate layer between the gate insulating layer and the interlayer dielectric layer.

Optionally, before step 1201, the method further comprises: sequentially forming a barrier layer and a flexible base layer on the flexible substrate. In some embodiments, step 1201 may include forming a stress control layer on the flexible substrate on which the flexible base layer is formed. In some embodiments, after the wiring layer is formed on the flexible substrate on which the second insulating layer is formed, the method further includes: sequentially forming a planarization layer, an anode, a pixel defining layer, a light-emitting layer and a cathode on the flexible substrate on which the wiring layer is formed.

All the foregoing optional technical solutions may be used in any combination to form additional optional embodiments of the present application which are thus omitted from being described in detail.

Refer to FIG. 13, FIG. 13 is a flowchart of a method for manufacturing a flexible display substrate according to another embodiment of the present application. This method can be used to manufacture the flexible display substrate 01 shown in FIG. 1, FIG. 2 or FIG. 7. This embodiment will be described by taking the flexible display substrate 01 shown in FIG. 7 as an example. Referring to FIG. 13, the method may include the following steps:

Step 1301, forming a barrier layer and/or a flexible base layer on a flexible substrate.

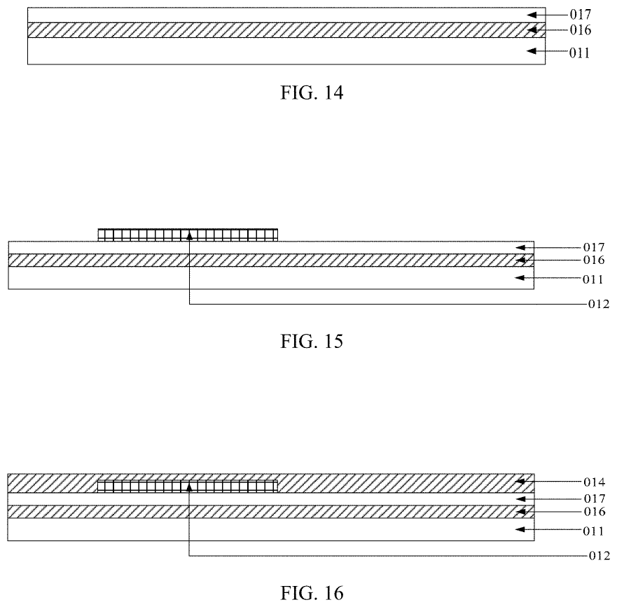

Refer to FIG. 14, FIG. 14 illustrates a schematic diagram of a barrier layer 016 and a flexible base layer 017 sequentially formed on a flexible substrate 011 according to an embodiment of the present application. The flexible substrate 011 may be a PI substrate. The material for forming the barrier layer 016 may be inorganic material such as SiOx, SiNx, Al₂O₃ or SiOxNy. Optionally, the barrier layer 016 is formed of organic material. The flexible base layer 017 may be PI.

Optionally, a layer of SiOx is formed as a barrier layer 016 on the flexible substrate 011. For example, a layer of SiOx may be deposited as a barrier layer 016 on the flexible substrate 011 by coating, magnetron sputtering, thermal evaporation or plasma enhanced chemical vapor deposition (PECVD). Then, optionally, a layer of PI is coated on the barrier layer 016 as the flexible base layer 017.

Step 1302, forming a stress control layer on the flexible substrate on which the barrier layer and/or the flexible base layer is/are formed. The flexible substrate has a bending region, and the orthographic projection of the stress control layer on the flexible substrate is at least located in the bending region.

Refer to FIG. 15, FIG. 15 is a schematic diagram of a stress control layer 012 formed on a flexible substrate 011 formed with a flexible base layer 017 according to an embodiment of the present application. Referring to FIGS. 1 and 15, the flexible substrate 011 has a bent area A1 (not labelled in FIG. 15), and the orthographic projection of the stress control layer 012 on the flexible substrate 011 is at least located in the bent area A1. Optionally, the orthographic projection of the stress control layer 012 on the flexible substrate 011 is located in the bending region A1. Optionally, the stress control layer 012 may have an opening. For example, the structure of the stress control layer 012 may be a mesh structure as shown in any of FIGS. 3 to 5. Optionally, as shown in FIG. 6, the stress control layer 012 is composed of a plurality of stress control strips having the same extending direction. In the embodiments of the present application, the stress control layer 012 may be formed of metal or non-metal material. For example, the stress control layer 012 can be a metal mesh. Optionally, the stress control layer 012 may be formed of a non-metal that is soft and flexible. The metal may be, for example, selected from a group consisting of Mo, Cu, Al, Ti, and any alloy thereof.

Optionally, a layer of metal Mo is deposited on the flexible substrate 011 having the flexible base layer 017 by coating, magnetron sputtering, thermal evaporation, PECVD, or the like to obtain a Mo layer, and then the Mo layer is processed by a single patterning process to obtain the stress control layer 012.

The patterning process can include photolithography and etching processes. In some embodiments, the patterning process can include photoresist coating, exposure, development, etching, photoresist stripping, and the like. In some embodiments, processing the Mo layer by a patterning process to obtain the stress control layer 012 may include: coating a layer of photoresist on the metal Mo layer to obtain a photoresist layer; exposing the photoresist layer with use of a mask or reticle to form a fully exposed region and a non-exposed region in the photoresist layer; selectively removing the photoresist by a development process, for example, the photoresist in the fully exposed region being completely removed, and the photoresist in the non-exposed region being retained; etching the region of the metal Mo layer corresponding to the fully exposed region with the photoresist as a mask; and finally stripping the photoresist in the non-exposed region. The region of the metal Mo layer that is retained serves as the stress control layer 012. It should be noted that, in the embodiment of the present application, the stress control layer 012 is formed by using a positive photoresist as an example, and the stress control layer 012 may be formed by using a negative photoresist. The present disclosure shall not be limited to the embodiments.

Step 1303, forming a first insulating layer on the flexible substrate formed with the stress control layer.

Refer to FIG. 16, FIG. 16 is a schematic diagram of a first insulating layer 014 formed on a flexible substrate 011 formed with a stress control layer 012 according to an embodiment of the present application. For the formation process of the first insulating layer 014, reference may be made to the formation process of the barrier layer 016 in step 1301, and details thereof are not described herein again; however, it should be understood that the present disclosure is not limited thereto.

Step 1304, forming a second insulating layer on the flexible substrate formed with the stress control layer. For example, a buffer layer, an active layer, a gate insulating layer, a gate electrode, and an interlayer dielectric layer are sequentially formed on a flexible substrate on which a stress control layer is formed. The buffer layer, the gate insulating layer, and the interlayer dielectric layer constitute a second insulating layer. The second insulating layer has a bent portion, and the bent portion includes an opening. The orthographic projection of the opening on the flexible substrate overlaps the bending region of the flexible substrate.

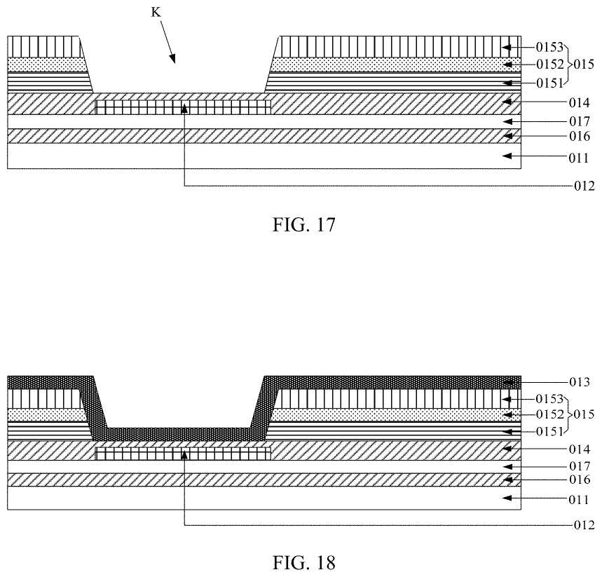

Refer to FIG. 17, FIG. 17 illustrates a schematic diagram of a buffer layer 0151, an active layer (not shown in FIG. 17), a gate insulating layer 0152, a gate (not shown in FIG. 17), and an interlayer dielectric layer 0153 sequentially formed on the flexible substrate 011 formed with the first insulating layer 014 according to an embodiment of the present application. In this embodiment, the buffer layer 0151, the gate insulating layer 0152, and the interlayer dielectric layer 0153 constitute the second insulating layer 015. The second insulating layer 015 has a bent portion having an opening K. The orthographic projection of the opening K on the flexible substrate 011 overlaps with the bending region (not labelled in FIG. 17) of the flexible substrate 011. Optionally, an orthographic projection of the opening K of the bend portion on the flexible substrate 011 may cover the bending region of the flexible substrate 011. Further optionally, the orthographic projection of the opening K of the bent portion on the flexible substrate 011 may coincide with the bending region of the flexible substrate 011.

In the embodiment of the present application, each of the buffer layer 0151, the gate insulating layer 0152, and the interlayer dielectric layer 0153 may include at least one film layer. In some embodiments, the the buffer layer 0151, the gate insulating layer 0152, and the interlayer dielectric layer 0153 may each be formed of inorganic material, such as SiOx, SiNx, Al₂O₃, or SiOxNy. Optionally, the buffer layer 0151, the gate insulating layer 0152, and the interlayer dielectric layer 0153 may each be formed of organic insulating material. The material for forming the buffer layer 0151, the gate insulating layer 0152, and the interlayer dielectric layer 0153 may be the same or different. The active layer may be an a-si active layer, an oxide active layer, or an LTPS active layer. The oxide active layer may be, for example, an IGZO active layer or an ITZO active layer. The material for forming the gate electrode may be selected from a group consisting of Mo, Cu, Al, Ti, or any alloy thereof.

Optionally, sequentially forming the buffer layer 0151, the active layer, the gate insulating layer 0152, the gate and the interlayer dielectric layer 0153 on the flexible substrate 011 formed with the first insulating layer 014 may include the following steps.

Step (1), a buffer layer 0151 is formed on the flexible substrate 011 on which the first insulating layer 014 is formed. The buffer layer may be formed of, for example, SiOx.

Step (2), an IGZO layer is formed on the flexible substrate 011 on which the buffer layer 0151 is formed. The IGZO layer is then processed by a patterning process to obtain an active layer.

In step (3), a gate insulating layer 0152 is formed on the flexible substrate 011 on which the active layer is formed. The gate insulating layer 0152 may be formed of, for example, Al₂O₃.

Step (4), a gate material layer (such as, but not limited to, Al layer) is formed on the flexible substrate 011 formed with the gate insulating layer 0152. The gate layer can then be processed by a patterning process to obtain a gate.

Step (5), an interlayer dielectric layer 0153 is formed on the flexible substrate 011 formed with the gate. As an example, the interlayer dielectric layer 0153 may be formed of SiOxNy.

Step (6), the second insulating layer 015 (including the buffer layer 0151, the gate insulating layer 0152, and the interlayer dielectric layer 0153) is processed by a patterning process to form a bend portion opening K on the second insulating layer 015.

Then, at Step 1304, a wiring layer is formed on the flexible substrate on which the second insulating layer is formed. In some embodiments, the wirings of the wiring layer are located partly in the bend portion and partly on the second insulating layer.

FIG. 18 is a schematic diagram of a method for forming a wiring layer on a flexible substrate 011 formed with the second insulating layer 015 according to an embodiment of the present application. Referring to FIGS. 17 and 18, the wiring layer includes wirings 013. The wiring 013s is located partly in the opening K of the bent portion, and is partly located on the second insulating layer 015. Since the wirings 013 are partly located in the bent portion K, and the orthographic projection of the bent portion K on the flexible substrate 011 overlaps with the bending region of the flexible substrate 011, the orthographic projection of the wirings 013 on the flexible substrate 011 partly located in the bending region. The wiring layer may be formed of conductive material(s), and specifically, the conductive material(s) may be selected from a group consisting of Mo, Cu, Al, Ti, and alloy materials thereof.

Optionally, a wiring material layer is formed on the flexible substrate 011 on which the second insulating layer 015 is formed, and then the wiring material layer is processed by a patterning process to obtain the wiring layer. The wiring material layer may include, but is not limited to, metal material such as copper (Cu). The wiring layer includes wirings 013.

It should be noted that the wiring 013 may be a gate wiring or a source drain wiring. In this specification, some descriptions are given with the wiring 013 as the source or drain wiring as an example. In some embodiments, the method of manufacturing the flexible display substrate may further include forming a source electrode and a drain electrode. Since the source electrode and the drain electrode are usually provided in the same layer as the source electrode and drain electrode wirings and can be formed by the same process, when the wirings 013 are the source/drain wirings, the source electrode and the drain electrode can also be formed during the formation of the wiring layer. In addition, the source electrode and the drain electrode are usually in contact with the active layer. Via holes may be formed in the interlayer dielectric layer 0153 and the gate insulating layer 0152 before the wiring layer is formed, so that the source electrode and the drain electrode respectively contact the active layer through the via holes.

In some embodiments of the present application, the flexible display substrate 01 is an OLED display substrate. The manufacturing method of the flexible display substrate may further include the following step 1305. Step 1305, sequentially forming a planarization layer, a first electrode (e.g., anode) layer, a pixel defining layer, a light emitting layer, and a second electrode (e.g., cathode) layer on the flexible substrate on which the wiring layer is formed.

Referring to FIG. 7, a schematic diagram after the planarization layer 018, the first electrode, the pixel defining layer 019, the light emitting layer, and the second electrodes are sequentially formed on the flexible substrate 011 having the wiring layer formed. The planarization layer 018 and the pixel defining layer 019 may each be formed of organic resin. The material for forming the anode and the cathode may each be ITO, IZO or ZnO:Al. The light emitting layer may be formed of organic light emitting material, electroluminescent material, or photoluminescent material.

Optionally, sequentially forming the planarization layer 018, the anode, the pixel defining layer 019, the light emitting layer, and the cathode on the flexible substrate 011 formed with the wiring layer may include the following steps.

Step (1), forming a planarization layer 018 on the flexible substrate 011 on which the wiring layer is formed. The planarization layer 018 may be formed of an organic resin.

Step (2), forming a first electrode (e.g., anode) material layer on the flexible substrate 011 formed with the planarization layer 018. For example, the first electrode material layer may include ITO or the like; however, the present disclosure is not limited thereto. Then, the electrode material layer is processed by a patterning process to obtain the first electrode (for example, anode) for the light-emitting element.

Step (3), forming a pixel defining layer 019 on the flexible substrate 011 on which the first electrode is formed. For example, an organic resin layer may be formed on the flexible substrate 011 on which the first electrode is formed, and then the organic resin layer is processed by a patterning process to obtain a pixel defining layer 019.

Step (4), forming a light-emitting layer on the flexible substrate 011 on which the pixel defining layer 019 is formed. For example, an organic light-emitting material layer is formed on the flexible substrate 011 on which the pixel defining layer 019 is formed, and then the organic light-emitting material layer is processed by a patterning process to obtain a light-emitting layer.

Step (5), forming a second electrode (for example, cathode) for the light-emitting element on the flexible substrate 011 on which the light-emitting layer is formed. The second electrode can include, but is not limited to, IZO. This step (5) is exemplified by the case where the cathode is a bulk electrode (that is, the entire flexible display substrate 01 has one cathode). If the cathode is a bulk electrode, the deposited IZO material layer can be processed by a patterning process after depositing IZO to obtain the cathode.

It should be noted that after forming the second electrode, a photo spacer layer, a package structure, and the like may also be formed. Further, since the flexible substrate 011 is flexible, the flexible substrate 011 can be provided on a rigid substrate such as a glass substrate or a ceramic substrate, and the above steps 1301 to 1305 are performed thereon. After performing the above steps 1301 to 1305, the flexible substrate may be separated from the hard substrate to obtain the flexible display substrate 01 as shown in FIG. 7. However, the present disclosure shall not be limited to the embodiments disclosed herein.

It should be noted that the sequence of the steps of the manufacturing method of the flexible display substrate according to the embodiments of the present application may be changed as needed. When needed, additional step(s) can also be incorporated, or some step(s) can also be omitted. Any variations of the method that are apparent for those skilled in the art on basis of the present disclosure are intended to be embraced by the scope of the present application.

According to an embodiment of the present application, there further provides a display device, which includes the flexible display substrate according to any of the above embodiments. The flexible display substrate 01 according to the above embodiment has a display surface and a non-display surface which are oppositely provided. The display surface has an edge area. In the display device, the edge region of the flexible display substrate 01 can be bent to the side of the non-display surface of the flexible display substrate 01. A region on the flexible display substrate 01 that is to bent may be referred to as a bending region of the flexible display substrate 01, and the bending region of the flexible display substrate 01 corresponds to the bending region of the flexible substrate 011. In some cases, the wiring layer is a wiring layer disposed in a frame region of the flexible substrate.

The display device may include, but is not limited to, a narrow bezel display device, a bezel-less display device, or a full screen display device. For example, the display device may include (but is not limited to): any product or part thereof that has a display function, such as a display panel, a wearable device such as a watch or a wristband, a mobile terminal such as a mobile phone or a tablet computer, a television set, a display, a notebook computer, a digital photo frame, a navigator, or the like.

The term “and/or” in the present application is merely an association relationship describing associated objects. For example, “M and/or N” may include the case that M exists separately, the case that M and N exist simultaneously, and the case that N exists separately.

The above provided is only the embodiments of the present application, and is not intended to limit the scope of the present application. Any modifications, substitutions, changes, equivalences, etc. that fall within the spirit and scope of the present disclosure are intended to be embraced by the protection scope of the present application.

What is claimed is:

1. A flexible display substrate comprising:
a flexible substrate; and
a stress control layer and a wiring layer provided on the flexible substrate,
wherein an orthographic projection of the stress control layer on the flexible substrate at least partly overlaps an orthographic projection of wirings of the wiring layer on the flexible substrate.

2. The flexible display substrate according to claim 1, wherein
the wiring layer is a wiring layer disposed in a frame region of the flexible substrate; and
the wirings in the wiring layer are configured for binding a circuit.

3. The flexible display substrate of claim 2 wherein:
the wiring is a source wiring or a drain wiring.

4. The flexible display substrate of claim 3, wherein the stress control layer has an opening.

5. The flexible display substrate of claim 4, wherein the stress control layer has a mesh structure having a plurality of openings.

6. The flexible display substrate of claim 5, wherein the stress control layer is a metal layer.

7. The flexible display substrate of claim 6, further comprising:
a first insulating layer disposed between the stress control layer and the wiring layer.

8. The flexible display substrate of claim 1, further comprising:
a second insulating layer disposed between the first insulating layer and the wiring layer, the second insulating layer including a bent portion which includes an opening,
wherein the orthographic projection of the opening of the bent portion on the flexible substrate overlaps with a bending region of the flexible substrate,
the wiring is located partly in the opening and partly on the second insulating layer.

9. The flexible display substrate of claim 8, wherein the second insulating layer comprises a buffer layer, a gate insulating layer, and an interlayer dielectric layer;
the flexible display substrate further includes:
an active layer disposed between the buffer layer and the gate insulating layer, and
a gate disposed between the gate insulating layer and the interlayer dielectric layer.

10. The flexible display substrate of claim 7, further comprising:
a second insulating layer disposed between the first insulating layer and the wiring layer, the second insulating layer having a bent portion including an opening through which a part of the first insulating layer is exposed,
wherein an orthographic projection of the bent portion on the flexible substrate overlaps with the bending region of the flexible substrate, and
wherein the wiring is partly located in the opening and partly on the second insulating layer.

11. The flexible display substrate of claim 1, further comprising:
a barrier layer and a flexible base layer disposed in sequence between the flexible substrate and the stress control layer, and
a planarization layer on the wiring layer and a first electrode for a light emitting element, a pixel defining layer, a light emitting layer, and a second electrode for the light emitting element in the display region.

12. The flexible display substrate according to claim 1, wherein the flexible display substrate has a display surface and a non-display surface which are oppositely disposed, the display surface having a bending region, wherein an orthographic projection of the stress control layer on the display surface at least partly located in the bending region.

13. A method of manufacturing a flexible display substrate, comprising:
forming a stress control layer on the flexible substrate; and
forming a wiring layer on the flexible substrate formed with the stress control layer,
wherein an orthographic projection of a wiring of the wiring layer on the flexible substrate and an orthographic projection of the stress control layer on the flexible substrate at least partly overlap.

14. The flexible display substrate according to claim 13, wherein the flexible display substrate has a display surface and a non-display surface which are oppositely disposed, the display surface having a bending region, and an orthographic projection of the stress control layer on the display surface is at least partly located in the bending region.

15. The method according to claim 13, further comprising:
before forming the wiring layer on the flexible substrate formed with the stress control layer, forming a first insulating layer on the flexible substrate formed with the stress control layer,
wherein forming a wiring layer on the flexible substrate formed with the stress control layer includes forming a wiring layer on the flexible substrate on which the first insulating layer is formed.

16. The method of claim 13 wherein the stress control layer is a mesh structure having a plurality of openings.

17. The method of claim 13 further comprising:
before forming a wiring layer on the flexible substrate formed with the stress control layer, forming a second insulating layer on the flexible substrate, wherein the second insulating layer has a bent portion including an opening, and an orthographic projection of the opening of the bent portion on the flexible substrate overlaps with a bending region of the flexible substrate;
wherein forming the wiring layer on the flexible substrate formed with the stress control layer includes: forming a wiring layer such that a wiring of the wiring layer is located partly in the opening and partly on the second insulating layer.

18. The method of claim 15 further comprising:
before forming the wiring layer on the flexible substrate formed with the stress control layer, forming a second insulating layer on the flexible substrate formed with the first insulating layer, wherein the second insulating layer has a bent portion including an opening that exposes a portion of the first insulating layer, and an orthographic projection of the bent portion on the flexible substrate overlaps with a bending region of the flexible substrate,
wherein forming the wiring layer on the flexible substrate formed with the stress control layer includes: forming a wiring layer such that a wiring of the wiring layer is located partly in the opening and partly on the second insulating layer.

19. A display device comprising a flexible display substrate of claim 1.

20. The display device of claim 19, wherein the flexible display substrate has a display surface and a non-display surface which are oppositely disposed, the display surface has a bending region, and an orthographic projection of the stress control layer on the display surface at least partly located in the bending region.
